(19) United States
(12) Patent Application Publication
(10) Pub. No.: US 2024/0036688 A1
(43) Pub. Date: Feb. 1, 2024

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Liang MA, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/623,269

(22) PCT Filed: Dec. 17, 2021
(86) PCT No.: PCT/CN2021/138995

§ 371 Date: Jun. 15, 2023

(30) Foreign Application Priority Data
Dec. 9, 2021 (CN) 202111495762.X

(51) Int. Cl. G06F 3/044; H10K 59/40; H10K 59/122; H10K 59/80

(52) U.S. Cl. CPC G06F 3/0444; H10K 59/40; H10K 59/122; H10K 59/873

(57) ABSTRACT

The present application discloses a display panel and a display device. The display panel comprises a display area, a bending area and a bonding area, and the bending area comprises a reguler bending sub-area and a thinning bending sub-area. The display panel also comprises a thin film transistor layer and a touch metal layer. The touch metal layer is located on the thin film transistor layer and comprises touch traces extending through the thinning bend sub-area to the bonding area; wherein, a thickness of the thin film transistor layer in the thinning bending sub-area is less than a thickness of the thin film transistor layer in the regular bending sub-area.

### TECHNICAL FIELD

The present application relates to a technical field of display, and in particular, to a display panel and and a display device having the same.

### BACKGROUND

In an organic light-emitting diode (OLED) display device, a touch display device provides a touch-based user interface that allows an user to intuitively and conveniently input data or instructions directly to a device instead of using a conventional data input system such as a button, keyboard or mouse. Therefore, the touch display device must be able to sense the touch performed by an user and accurately determine touch coordinates. According to different sensing technologies, it can be divided into four types: resistive type, capacitive type, optical type and sonic type. At present, most of the OLED display screens on the market adopt a capacitance type touch panel, which uses capacitance changes caused by electrostatic bonding of finger and sensing units to detect induced coordinates.

Direct on touch (DOT) has gradually become the most popular process in place of add-on method. DOT refers to embedding a touch panel in a film layer above a substrate. It is common to prepare a TP layer above an encapsulation layer. Compared to an add-on touch structure, DOT has a slimmer structure and a higher transmittance, and can be used on a flexible display substrate. DOT is currently divided into two types: self-contained (SDOT) and mutual-contained (MDOT). SDOT is to detect changes of the capacitance of each sensing unit. MDOT is to detect the capacitance formed between two cross sensing blocks.

Wherein, in the touch panel, a touch electrode is connected to a bezel area of a panel through a touch trace, and the touch trace passes through a wire changing hole and is connected to a lower metal layer, and is electrically connected to a bonding terminal through the lower metal layer. However, an inorganic layer in the encapsulation layer extends to a lower bezel area during the deposition process, and its thickness is getting thinner and thinner. In the related art, in order to prevent the inorganic layer from remaining in the wire changing hole of the touch trace, the wire changing hole is arranged outside a coverage area of the inorganic layer, so that the wire changing hole is arranged away from the display area, causing the bezel width of a touch panel to become larger, which is disadvantageous to the narrow bezel requirement of a touch panel.

### Technical Problem

An embodiment of the present application provides a display panel and a display device, which can reduce the bezel width of a display panel, reduce stress on a touch trace, and improve yield of the touch trace.

### Technical Solution

An embodiment of the present application provide a display panel, comprising a display area, a bending area on one side of the display area, and a bonding area on one side of the bending area away from the display area, wherein the bending area comprises a regular bending sub-area and a thinning bending sub-area;
the display panel further comprises:
a substrate;
a thin film transistor layer disposed on one side of the substrate, wherein the thin film transistor layer comprises a first metal layer and an organic spacer layer disposed on one side of the first metal layer away from the substrate, and the first metal layer comprises at least one first metal trace starting from the display area and extending to the bonding area through the bending area; and
a touch metal layer disposed on one side of the thin film transistor layer away from the substrate, wherein the touch metal layer comprises a touch electrode disposed in the display area and a touch trace electrically connected to the touch electrode, and the touch trace passes through the thinning bending sub-area and extends to the bonding area;
wherein a thickness of the thin film transistor layer in the thinning bending sub-area is less than a thickness of the thin film transistor layer in the regular bending sub-area.

In an embodiment of the present application, the organic spacer layer comprises a first organic portion disposed in the display area and a second organic portion disposed in the bending area;
in the bending area, the first metal trace is disposed between the second organic portion and the substrate, the second organic portion is provided with a first groove in the thinning bending sub-area, and the touch trace extends to the bonding area through the first groove.

In an embodiment of the present application, the organic spacer layer comprises a planarization layer, a pixel definition layer, and a spacer layer which are sequentially stacked on the first metal layer;
in the bending area, a bottom surface of the first groove of the second organic portion at least penetrates into the pixel definition layer.

In an embodiment of the present application, in the bending area, the bottom surface of the first groove of the second organic portion penetrates into the planarization layer.

In an embodiment of the present application, the thin film transistor layer further comprises an organic insulating layer disposed on one side of the first metal layer away from the organic spacer layer, the thin film transistor layer is provided with a second groove in the thinning bending sub-area, the second groove passes through the organic spacer layer and a portion of the organic insulating layer, and the touch trace extends to the bonding area through the second groove.

In an embodiment of the present application, the thin film transistor layer further comprises an opening provided in the bending area, the organic insulating layer is filled in the opening and protrudes from a top surface of the opening, a bottom surface of the second groove penetrates into the organic insulating layer and is flush with the top surface of the opening.

In an embodiment of the present application, the touch trace is between the display area and the bending area, and is not electrically connected with the first metal trace through any connection hole in the organic spacer layer.

In an embodiment of the present application, in the bending area, the first metal trace is disposed in the regular bending sub-area.

In an embodiment of the present application, the display panel further comprises:
An encapsulation layer disposed on one side of the thin film transistor layer away from the substrate, wherein the encapsulation layer covers the display area and extends to a portion between the display area and the bending area;
wherein the encapsulation layer and the organic spacer layer are at least partially overlapped between the display area and the bending area, and the touch trace is arranged to cover the encapsulation layer and the organic spacer layer between the display area and the bending area.

According to the above object of the present application, a display device is provided, the display device comprises a display panel and a device body, wherein the display panel and the device body are integrated;
the display panel comprises a display area, a bending area on one side of the display area, and a bonding area on one side of the bending area away from the display area, wherein the bending area comprises a regular bending sub-area and a thinning bending sub-area; the display panel further comprises:
a substrate;
a thin film transistor layer disposed on one side of the substrate, wherein the thin film transistor layer comprises a first metal layer and an organic spacer layer disposed on one side of the first metal layer away from the substrate, and the first metal layer comprises at least one first metal trace starting from the display area and extending to the bonding area through the bending area; and
a touch metal layer disposed on one side of the thin film transistor layer away from the substrate, wherein the touch metal layer comprises a touch electrode disposed in the display area and a touch trace electrically connected to the touch electrode, and the touch trace passes through the thinning bending sub-area and extends to the bonding area;
wherein a thickness of the thin film transistor layer in the thinning bending sub-area is less than a thickness of the thin film transistor layer in the regular bending sub-area.

In an embodiment of the present application, the organic spacer layer comprises a first organic portion disposed in the display area and a second organic portion disposed in the bending area;
in the bending area, the first metal trace is disposed between the second organic portion and the substrate, the second organic portion is provided with a first groove in the thinning bending sub-area, and the touch trace extends to the bonding area through the first groove.

In an embodiment of the present application, the organic spacer layer comprises a planarization layer, a pixel definition layer, and a spacer layer which are sequentially stacked on the first metal layer;
in the bending area, a bottom surface of the first groove of the second organic portion at least penetrates into the pixel definition layer.

In an embodiment of the present application, in the bending area, the bottom surface of the first groove of the second organic portion penetrates into the planarization layer.

In an embodiment of the present application, the thin film transistor layer further comprises an organic insulating layer disposed on one side of the first metal layer away from the organic spacer layer, the thin film transistor layer is provided with a second groove in the thinning bending sub-area, the second groove passes through the organic spacer layer and a portion of the organic insulating layer, and the touch trace extends to the bonding area through the second groove.

In an embodiment of the present application, the thin film transistor layer further comprises an opening provided in the bending area, and the organic insulating layer is filled in the opening and protrudes from a top surface of the opening, and a bottom surface of the second groove penetrates into the organic insulating layer and is flush with the top surface of the opening.

In an embodiment of the present application, the touch trace is between the display area and the bending area, and is not electrically connected with the first metal trace through any connection hole in the organic spacer layer.

In an embodiment of the present application, in the bending area, the first metal trace is disposed in the regular bending sub-area.

In an embodiment of the present application, the display panel further comprises:
an encapsulation layer disposed on one side of the thin film transistor layer away from the substrate, wherein the encapsulation layer covers the display area and extends to a portion between the display area and the bending area;
wherein the encapsulation layer and the organic spacer layer are at least partially overlapped between the display area and the bending area, and the touch trace is arranged to cover the encapsulation layer and the organic spacer layer between the display area and the bending area.

### Technical Effects

Compared with the prior art, in the present application, the touch trace directly passes through the bending area and extends to the bonding area for bonding, there is no need to open a hole between the bending area and the display area for wire changing, and further there is no need to consider the phenomenon of poor contact caused by the fact that the encapsulation layer is too thin to be effectively etched because it extends into the wire exchanging hole, so that distance between the bending area and the display area can be reduced, and the bezel width of the display panel can be reduced, thus achieving the purpose of a narrow bezel display panel. Further, in the present application, the touch trace is disposed in the thinning bending sub-area, and the thin film transistor layer in the thinning bending sub-area is thinned, so that the position of the touch trace in the bending area can be closer to the neutral surface of the display panel, so as to reduce the stress on the touch trace and improve yield of the touch trace.

### BRIEF DESCRIPTION OF THE DRAWINGS

The technical solutions and other beneficial effects of the present application will be apparent from detailed description of the specific embodiments of the present application with reference to the accompanying drawings.

FIG. 1 is a schematic structural diagram of a display panel in the related technology.

FIG. 2 is a schematic diagram of a plane structure of a display panel according to an embodiment of the present application.

FIG. 3 is a schematic structural diagram of a display panel corresponding to a thinning bending sub-area according to an embodiment of the present application.

FIG. 4 is a schematic structural diagram of a display panel corresponding to a regular bending sub-area according to an embodiment of the present application.

FIG. 5 is a schematic structural diagram of another display panel corresponding to a thinning bending sub-area according to an embodiment of the present application.

FIG. 6 is a schematic structural diagram of another display panel corresponding to a thinning bending sub-area according to an embodiment of the present application.

FIG. 7 is a schematic structural diagram of another display panel corresponding to a thinning bending sub-area according to an embodiment of the present application;

FIG. 8 is a bar chart of stress simulation results of touch traces in a bending area of a display panel according to embodiments of the present application.

### DETAILED DESCRIPTION

Hereinafter, technical solution in embodiments of the present application will be clearly and completely described with reference to the accompanying drawings in embodiments of the present application. Apparently, the described embodiments are part of, but not all of, the embodiments of the present application. All the other embodiments, obtained by a person with ordinary skill in the art on the basis of the embodiments in the present application without expenditure of creative labor, belong to the protection scope of the present application.

The following disclosure provides many different embodiments or examples for implementing different structures of the present application. In order to simplify the disclosure of the present application, components and arrangements of specific embodiments are described below. Of course, they are merely examples and are not intended to limit the present application. Furthermore, the present application may repeat reference numbers and/or reference letters in different embodiments. Such repetition is the sake of simplicity and clarity, which in itself does not indicate the relationship between the various embodiments and/or arrangements discussed. In addition, the present application provides examples of various specific processes and materials, but those skilled in the art may recognize application of other processes and/or use of other materials.

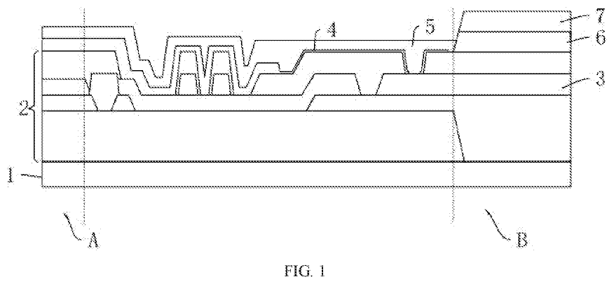

Referring to FIG. 1, in the related art, a display panel comprises a substrate 1, a thin film transistor array layer 2 disposed on the substrate 1, an encapsulation layer 4 disposed on the thin film transistor array layer 2, a touch lead 5 disposed on the encapsulation layer 4, a pixel definition layer 6 disposed on the thin film transistor array layer 2, and a dam layer 7. The display panel comprises a display area A and a bending area B, the thin film transistor array layer 2 comprises a signal line 3, and the touch lead 5 is subjected to wire changing between the display area A and the bending area B through a wire changing hole, and extends to a bonding area for bonding. However, due to the process reason, thickness of the encapsulation layer 4 on the side close to the bending area B gradually decreases, and thickness of the encapsulation layer 4 is relatively thin, it is difficult to effectively etch, and the wire change hole needs to be provided in a direction away from the display area A, so as to avoid the encapsulation layer 4 remaining in the wire change hole, thereby increasing the distance between the display area A and the bending area B, that is, increasing the bezel width of the display panel, which is not conducive to display of narrow bezel.

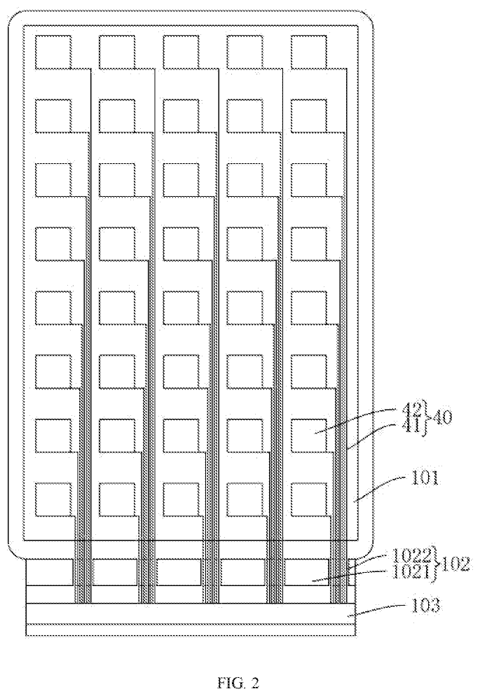

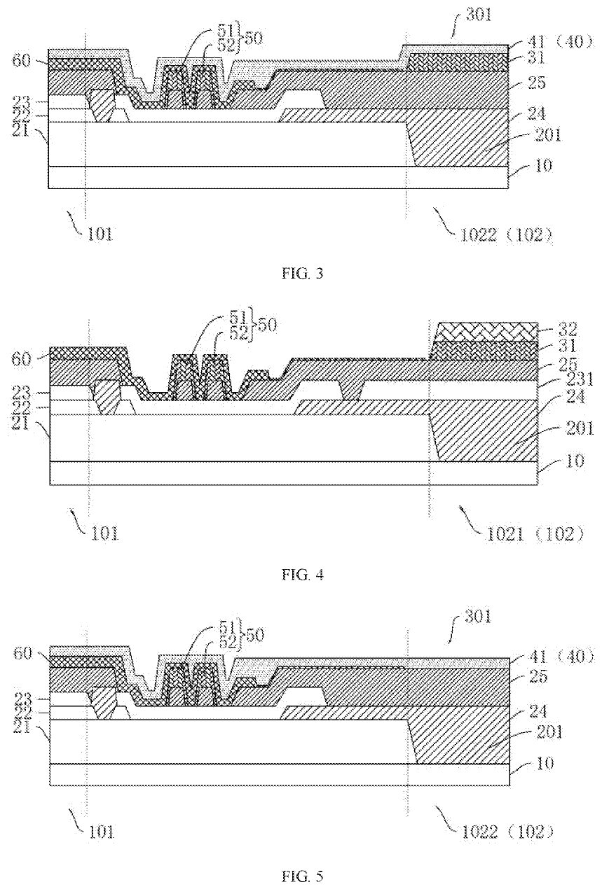

An embodiment of the present application provides a display panel. Referring to FIGS. 2, 3 and 4, the display panel comprises a display area 101, a bending area 102 on one side of the display area 101, and a bonding area 103 on the side of the bending area 102 away from the display area 101, wherein the bending area 102 comprises a regular bending sub-area 1021 and a thinning bending sub-area 1022.

Further, the display panel further comprises a substrate 10, a thin film transistor layer, and a touch metal layer 40.

The thin film transistor layer is disposed on one side of the substrate 10, wherein the thin film transistor layer comprises a first metal layer 23 and an organic spacer layer disposed on one side of the first metal layer 23 away from the substrate 10, and the first metal layer 23 comprises at least one first metal trace 231 starting from the display area 101 and extending to the bonding area 103 through the bending area 102. The touch metal layer 40 is disposed on one side of the thin film transistor layer away from the substrate 10, and the touch metal layer comprises a touch electrode 42 disposed in the display area 101 and a touch trace 41 electrically connected to the touch electrode 42, and the touch trace 41 passes through the thinning bending sub-area 1022 and extends to the bonding area 103.

Wherein, a thickness of the thin film transistor layer in the thinning bending sub-area 1022 is less than a thickness of the thin film transistor layer in the regular bending sub-area 1021.

In the application process, in an embodiment of the present application, the touch traces are arranged to directly pass through the thinning bending sub-area area 1022 and extend to the bonding area 103 for bonding, so that there is no need to open a hole between the bending area and the display area for wire changing. Similarly, there is no need to consider the phenomenon of poor contact caused by the fact that the encapsulation layer is too thin to be effectively etched because it extends into the wire exchanging hole, so that distance between the bending area 102 and the display area 101 can be reduced, and the bezel width of the display panel can be reduced, thus achieving the purpose of a narrow bezel display panel. Further, in the present application, the touch trace 41 is disposed in the thinning bending sub-area 1022, and the thin film transistor layer in the thinning bending sub-area 1022 is thinned, so that the position of the touch trace 41 in the bending area 102 can be closer to the neutral surface of the display panel, so as to reduce the stress on the touch trace 41 and improve yield of the touch trace 41.

Specifically, in an embodiment of the present application, please continue to refer to FIGS. 2, 3 and 4, the display panel comprises a display area 101 and a non-display area adjacent to the display area 101, and the non-display area comprises a bending area 102 disposed on one side of the display area 101 and a bonding area 103 disposed on the side of the bending area 102 away from the display area 101.

The display panel further comprises a substrate 10, a thin film transistor layer, an encapsulation layer 60, and a touch metal layer 40. The thin film transistor layer is disposed on the substrate 10. The thin film transistor layer comprises an inorganic layer 21, a second metal layer 22 disposed on the inorganic layer 21, an organic insulating layer 24 disposed on the second metal layer 22, a first metal layer 23 disposed on the organic insulating layer 24, and an organic spacer layer disposed on the first metal layer 23. In this embodiment, the organic spacer layer comprises a planarization layer 25 disposed on the first metal layer 23, a pixel definition layer 31 disposed on the planarization layer 25, and a spacer layer 32 disposed on the pixel definition layer 31.

It should be noted that the inorganic layer 21 comprises a plurality of inorganic insulating layer sub-layers and a thin film transistor device, such as an active layer, a gate, a gate line, etc., coated between the plurality of inorganic insulating layer sub-layers. The second metal layer 22 may comprise a source, a drain, a data line, etc. The first metal layer 23 may comprise a reset signal line and a first metal trace 231 located at least in the non-display area. It can be understood that, in the drawings provided by the embodiments of the present application, only a schematic structural diagram of the display panel close to the non-display area side is shown, while the structure of the display panel located on the side of the display area 101, for example, the arrangement of the thin film transistor array, the gate lines and the data lines, etc. can be realized by referring to conventional processes, and details are not described herein.

Wherein, the display panel needs to be bent at the position of the bending area 102, so that the bonding area 103 is bent to the back surface of the display panel, and the thin film transistor layer is provided with an opening 201 in the bending area 102, and the organic insulating layer 201 is filled in the opening 201 and protrudes from the top surface of the opening 201 to play a role of buffering the bending stress. The first metal layer 23 is disposed on the organic insulating layer 24, and the planarization layer 25 is disposed on the first metal layer 23. Specifically, the first metal trace 231 extends to the regular bending sub-area 1021 and is located on an upper surface of the organic insulating layer 24, and the first metal trace 231 starts from the display area 101 and extends to the bonding area 103 through the bending area 102 for bonding.

Further, the organic spacer layer comprises a first organic portion located in the display area 101 and a second organic portion located in the bending area 102, wherein the pixel definition layer 31 in the first organic portion are provided with a plurality of pixel openings in the display area 101, and each pixel opening is provided with a light emitting unit. The first organic portion is provided with a retaining wall surrounding the pixel openings in the display area 101 to prevent ink from overflowing outside the pixel openings during preparation of the light emitting units. The planarization layer 25, the pixel definition layer 31, and the spacer layer 32 in the second organic portion all cover the first metal traces 231 to provide protection for the first metal traces 231.

On the other hand, the pixel definition layer 31 and the planarization layer 25 are laminated in an area between the display area 101 and the bending area 102 to form a retaining wall structure 50.

In an embodiment of the present application, the retaining wall structure comprises a first retaining wall 51 located between the display area 101 and the bending area 102 and a second retaining wall 52 located between the first retaining wall 51 and the bending area 102.

The encapsulation layer 60 is disposed on the thin film transistor layer, and the encapsulation layer 60 comprises an inorganic encapsulation sub-layer and an organic encapsulation sub-layer, which may be specifically a first inorganic sub-layer, an organic sub-layer and a second inorganic sub-layer that are stacked. The inorganic encapsulation sub-layer comprises a first inorganic sub-layer and a second inorganic sub-layer, wherein the inorganic encapsulation sub-layers cover the display area 101 and extend to one side of the second retaining wall 52 away from the display area 101, and on one side of the second retaining wall 52 away from the display area 101. The thickness of the inorganic encapsulation sub-layer near the second retaining wall 52 is greater than the thickness of the inorganic encapsulation sublayer away from the second retaining wall 52.

Furthermore, boundary of the side of the encapsulation layer 101 away from the display area 101 is located between the display area 101 and the bending area 102, and at least partially overlaps with the organic spacer layer; and boundary of the encapsulation layer 101 may be located between the retaining wall structure 50 and the bending area 102, and the encapsulation layer 60 covers an upper surface of the planarization layer 25 in the area between the retaining wall structure 50 and the bending area 102.

The touch metal layer 40 is disposed on one side of the encapsulation layer 60 away from the substrate 10. The touch metal layer 40 comprises a plurality of touch electrodes 42 distributed in an array in the display area 101 and touch traces 41 connected to the touch electrodes 42 and extending into the non-display area.

Specifically, in an embodiment of the present application, one end of the touch trace 41 is connected to a corresponding touch electrode 42, and the other end extends from the display area 101 to the thinning bending sub-area 1022, and further extends to the bonding area 103 for bonding. That is to say, there is no need for the touch trace 41 in embodiments of the present application to open a hole between the display area 101 and the bending area 102 for wire changing. Similarly, there is no need to consider the phenomenon of poor contact caused by the fact that the encapsulation layer 60 is too thin to be effectively etched because it extends into the wire exchanging hole, so that distance between the bending area 102 and the display area 101 can be reduced, and the bezel width of the display panel can be reduced, thus achieving the purpose of a narrow bezel display panel.

Further, in an embodiment of the present application, the thickness of the thin film transistor layer in the thinning bending sub-area 1022 is less than a thickness of the thin film transistor layer in the regular bending sub-area 1021. Specifically, the thickness of the organic film layer in the bending sub-area 1022 may be less than the thickness of the organic film layer in the regular bending sub-area 1021. Optionally, the organic film layer may comprise an organic insulating layer 24, a planarization layer 25, a pixel definition layer 31, and a spacer layer 32.

In an embodiment of the present application, the second organic portion is provided with a first groove 301 in the thinning bending sub-area 1022, and the touch trace 41 is disposed in the first groove 301.

Specifically, the spacer layer 32 is provided with a first groove 301 in the thinning bending sub-area 1022, that is, the touch trace 41 passes through the first groove 301 and extends into the bonding area 103 for bonding.

Optionally, the depth of the first groove 301 is less than or equal to the thickness of the spacer layer 32, and when the depth of the first groove 301 is equal to the thickness of the spacer layer 32, the bottom surface of the first groove 301 is the upper surface of the pixel definition layer 31.

The pixel definition layer 31, the spacer layer 32, and the planarization layer 25 cover the first metal trace 231 in the reguler bending sub-area 1021 to protect the first metal trace 231.

Further, in this embodiment, the first metal traces 231 are located in the reguler bending sub-area 1021, that is, in embodiments of the present application, compared with the related art, not only the organic film layer in the thinning bending sub-area 1022 is thinned, but the first metal traces 231 may be also disposed outside the thinning bending sub-area 1022 to further reduce the bending stress to the touch traces 41 in the thinning bending sub-area 1022.

In summary, it can be understood that in the display panel, its neutral surface is close to the inorganic layer 21. Therefore, in an embodiment of the present application, the thickness of the thin film transistor layer in the thinning bending sub-area 1022 is reduced by providing the first groove 301 in the spacer layer 32 in the thinning bending sub-area 1022, so that the touch traces 41 are disposed closer to the neutral surface of the display panel, and the bending stress received by the touch traces 41 can be reduced when bending is carried out in the bending area 102, thereby improving yield of the touch traces 41. Further, in an embodiment of the present application, the distance between the bending area 102 and the display area 101 may be reduced, and the bezel width of the display panel can be reduced, thus achieving the purpose of a narrow bezel display panel.

In another embodiment of the present application, referring to FIGS. 2, 4 and 5, this embodiment differs from the previous embodiments in that the thickness of the thin film transistor layer in the thinning bending sub-area 1022 is further reduced.

In this embodiment, the spacer layer 32 and the pixel definition layer 31 are provided with a first groove 301 in the thinning bending sub-area 1022. That is to say, the depth of the first groove 301 is greater than the thickness of the spacer layer 32 in the thinning bending sub-area 1022, and is less than or equal to the sum of the thickness of the spacer layer 32 and the pixel definition layer 31 in the thinning bending sub-area 1022. The touch trace 41 is disposed in the first groove 301, that is, the touch trace 41 passes through the first groove 301 and extends to the bonding area 103 for bonding.

Optionally, the depth of the first groove 301 is equal to the sum of the thickness of the spacer layer 32 and the pixel definition layer 31, that is, the bottom surface of the first groove 301 is the upper surface of the planarization layer 25.

The pixel definition layer 31, the spacer layer 32, and the planarization layer 25 cover the first metal trace 231 in the reguler bending sub-area 1021 to protect the first metal trace 231.

In summary, it can be understood that in the display panel, its neutral surface is close to the inorganic layer 21. Therefore, in an embodiment of the present application, the thickness of the thin film transistor layer in the thinning bending sub-area 1022 is further reduced by providing the first groove 301 in the thinning bending sub-area 1022 in the spacer layer 32 and the pixel definition layer 31, so that the touch traces 41 are disposed closer to the neutral surface of the display panel than in the previous embodiment, thereby reducing bending stress received by the touch traces 41 can be reduced when bending is carried out in the bending area 102 and improving yield of the touch traces 41. Further, in an embodiment of the present application, the distance between the bending area 102 and the display area 101 may be reduced, and the bezel width of the display panel can be reduced, thus achieving the purpose of a narrow bezel display panel.

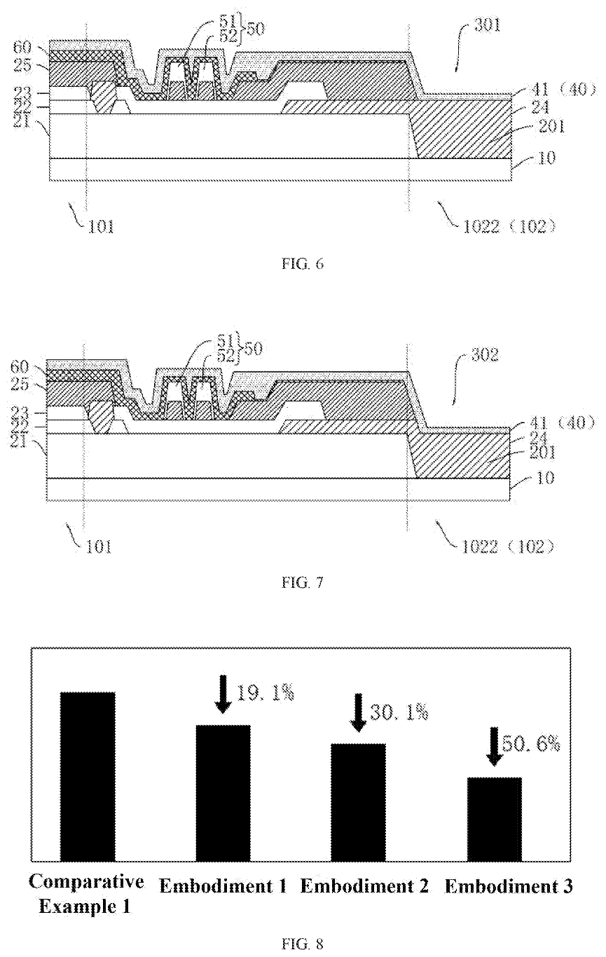

In another embodiment of the present application, referring to FIGS. 2, 4 and 6, this embodiment differs from the previous embodiment in that the thickness of the thin film transistor layer in the thinning bending sub-area 1022 is further reduced.

In this embodiment, the spacer layer 32, the pixel definition layer 31, and the planarization layer 25 are provided with a first groove 301 in the thinning bending sub-area 1022. That is, in this embodiment, the depth of the first groove 301 is greater than the sum of the thickness of the spacer layer 32 and the pixel definition layer 31 in the thinning bending sub-area 1022, and is less than or equal to the sum of the thickness of the spacer layer 32, the pixel definition layer 31, and the planarization layer 25 in the thinning bending sub-area 1022. That is, the touch traces 41 pass through the first groove 301 and extend to the bonding area 103 for bonding.

Optionally, the depth of the first groove 301 is equal to the sum of the thickness of the spacer layer 32, the pixel definition layer 31, and the planarization layer 25, that is, the bottom surface of the first groove 301 is the upper surface of the organic insulating layer 24.

While in the in the reguler bending sub-area 1021, the pixel definition layer 31, the spacer layer 32, and the planarization layer 25 cover the first metal traces 231 to protect the first metal traces 231.

In summary, it can be understood that in the display panel, its neutral surface is close to the inorganic layer 21. Therefore, in an embodiment of the present application, the thickness of the thin film transistor layer in the thinning bending sub-area 1022 is further reduced by providing the first groove 301 in the thinning bending sub-area 1022 in the spacer layer 32, the pixel definition layer 31, and the planarization layer 25, so that the touch traces 41 are disposed closer to the neutral surface of the display panel than in the previous embodiment, thereby reducing bending stress received by the touch traces 41 can be reduced when bending is carried out in the bending area 102 and improving yield of the touch traces 41. Further, in an embodiment of the present application, the distance between the bending area 102 and the display area 101 may be reduced, and the bezel width of the display panel can be reduced, thus achieving the purpose of a narrow bezel display panel.

In another embodiment of the present application, referring to FIGS. 2, 4 and 7, this embodiment differs from the previous embodiment in that the thickness of the thin film transistor layer in the thinning bending sub-area 1022 is further reduced.

In this embodiment, the spacer layer 32, the pixel definition layer 31, the planarization layer 25, and the organic insulating layer 24 are provided with a second groove 302 in the thinning bending sub-area 1022. Further, the depth of the second groove 302 is greater than the sum of the thickness of the spacer layer 32, the pixel definition layer 31, and the planarization layer 25, and is less than the sum of the thickness of the spacer layer 32, the pixel definition layer 31, the planarization layer 25, and the organic insulating layer 24. That is, the touch traces 41 pass through the second groove 302 and extend to the bonding area 103 for bonding.

In this embodiment, the second groove 302 passes through the spacer layer 32, the pixel definition layer 31, the planarization layer 25, and a portion of the organic insulating layer 24.

Optionally, the bottom surface of the second groove 302 is flush with the top surface of the opening 201.

In the reguler display sub-area 1021, the pixel definition layer 31, the spacer layer 32, and the planarization layer 25 cover the first metal traces 231 to protect the first metal traces 231.

In summary, it can be understood that in the display panel, its neutral surface is close to the inorganic layer 21. Therefore, in an embodiment of the present application, the thickness of the thin film transistor layer in the thinning bending sub-area 1022 is further reduced by providing the second groove 302 in the thinning bending sub-area 1022 in the spacer layer 32, the pixel definition layer 31, the planarization layer 25, and the organic insulating layer 24, so that the touch traces 41 are disposed closer to the neutral surface of the display panel than in the previous embodiment, thereby reducing bending stress received by the touch traces 41 can be reduced when bending is carried out in the bending area 102 and improving yield of the touch traces 41. Further, in an embodiment of the present application, the distance between the bending area 102 and the display area 101 may be reduced, and the bezel width of the display panel can be reduced, thus achieving the purpose of a narrow bezel display panel.

It should be noted that in the above embodiment, the organic film layer in the thin film transistor layer is thinned from top to bottom in sequence, while in other embodiments of the present application, the planarization layer 25 and the organic insulating layer 24 may be thinned in the portion of the thinning bending sub-area 1022, and the pixel definition layer 31 and the spacer layer 32 are not thinned in the portion of the thinning bending sub-area 1022. Alternatively, in the thinning bending sub-area 1022, the pixel definition layer 31, the planarization layer 25, and/or the organic insulating layer 24 are thinned, while the thickness of the spacer layer 32 is not changed. Alternatively, in the thinning bending sub-area 1022, the spacer layer 32, the planarization layer 25, and/or the organic insulating layer 24 are thinned, while the thickness of the pixel definition layer 31 is not changed. That is, in embodiments of the present application, any one or more of the spacer layer 32, the pixel definition layer 31, the planarization layer 25, and the organic insulating layer 24 in the thin film transistor layer may be thinned to reduce the thickness of the thin film transistor layer in the thinning bending sub-area 1022.

In addition, please refer to FIG. 8, which is a bar chart of stress simulation results of touch traces 41 in a bending area 102 of a display panel according to embodiments of the present application, involving embodiment 1, embodiment 2, embodiment 3 and comparative example 1. Wherein in embodiment 1, the spacer layer 32 in the thinning bending sub-area 1022 is removed; in embodiment 2, the spacer layer 32 and the pixel definition layer 31 in the thinning bending sub-area 1022 are removed; in embodiment 3, the spacer layer 32, the pixel definition layer 31 and the planarization layer 25 in the thinning bending sub-area 1022 are removed; and in comparative example 1, the thinning bending sub-area 1022 is not thinned, that is, the touch traces 41 are located on the spacer layer 32 and the pixel definition layer 31 in the bending area 102.

As can be seen from FIG. 8, when compared with comparative example 1, the stress received by the touch traces 41 in the bending area is reduced by 19.1% in embodiment 1; when compared with embodiment 1, the stress received by the touch traces 41 in the bending area is reduced by 30.1% in embodiment 2; and when compared with embodiment 1, the stress received by the touch traces 41 in the bending area is reduced by 50.6% in embodiment 3, that is, the closer the touch traces 41 are to the inorganic layer 21 in the bending area 102, the less the stress the touch traces 41 are subjected to, indicating that the display panel provided by embodiments of the present application can effectively reduce the stress on the touch traces 41 when they directly pass through the bending area 102, and improve yield of the touch traces 41.

In addition, in the method for preparing the display panel provided by embodiments of the present application, the method of thinning each film layer in the thinning bending sub-area 1022 may be to directly remove the film layer in the patterning process when preparing the film layer, or to use a semi-transparent mask plate to make the thickness of a portion of the film layer in the thinning bending sub-area 1022 thinner.

For example, when the pixel definition layer 31 in the thinning bending sub-area 1022 is thinned, and when the pixel definition layer 31 is patterned to form a pixel opening, a portion located in the thinning bending sub-area 1022 may be simultaneously removed, or a semi-transparent mask is used so that a portion of the thickness of the pixel definition layer 31 located in the thinning bending sub-area 1022 is less than a portion of the thickness of the display region surrounding the pixel opening.

In conclusion, in embodiments of the present application, the thickness of the thin film transistor layer in the thin bending sub-are 1022 is reduced, so that the touch traces 41 are disposed closer to the neutral surface of the display panel, and the bending stress when the touch traces 41 are bent in the bending are 102 can be reduced, thereby improving yield of the touch traces 41. Further, in embodiments of the present application, the distance between the bending area 102 and the display area 101 may be reduced, and the bezel width of the display panel can be reduced, thus achieving the purpose of a narrow bezel display panel.

In addition, an embodiment of the present application further provides a display device, which comprises a display panel and a device body, and the display panel and the device body are integrated.

In the above embodiments, the descriptions of each embodiment has its own focus, for the parts that are not detailed in a certain embodiment, please refer to the related descriptions of other embodiments.

The display panel and display device provided in embodiments of the present application are described in detail above. The principles and embodiments of the present application are described by using specific embodiments herein. The description of the above embodiments is merely intended to help understand the technical solutions and core ideas of the present application. A skilled person in the art shall understand that it is still possible to modify the technical solutions described in the previous embodiments or to equivalent replace some of the technical features. However, these modifications or substitutions do not make the essence of the corresponding technical solutions depart from the scope of the technical solutions of each embodiment of the present application.

What is claimed is:

1. A display panel, comprising a display area, a bending area on one side of the display area, and a bonding area on one side of the bending area away from the display area, wherein the bending area comprises a regular bending sub-area and a thinning bending sub-area;
the display panel further comprises:
a substrate;
a thin film transistor layer disposed on one side of the substrate, wherein the thin film transistor layer comprises a first metal layer and an organic spacer layer disposed on one side of the first metal layer away from the substrate, and the first metal layer comprises at least one first metal trace starting from the display area and extending to the bonding area through the bending area; and
a touch metal layer disposed on one side of the thin film transistor layer away from the substrate, wherein the touch metal layer comprises a touch electrode disposed in the display area and a touch trace electrically connected to the touch electrode, and the touch trace passes through the thinning bending sub-area and extends to the bonding area;
wherein a thickness of the thin film transistor layer in the thinning bending sub-area is less than a thickness of the thin film transistor layer in the regular bending sub-area.

2. The display panel according to claim 1, wherein the organic spacer layer comprises a first organic portion disposed in the display area and a second organic portion disposed in the bending area;
in the bending area, the first metal trace is disposed between the second organic portion and the substrate, the second organic portion is provided with a first groove in the thinning bending sub-area, and the touch trace extends to the bonding area through the first groove.

3. The display panel according to claim 2, wherein the organic spacer layer comprises a planarization layer, a pixel definition layer, and a spacer layer which are sequentially stacked on the first metal layer;
in the bending area, a bottom surface of the first groove of the second organic portion at least penetrates into the pixel definition layer.

4. The display panel according to claim 3, wherein in the bending area, the bottom surface of the first groove of the second organic portion penetrates into the planarization layer.

5. The display panel according to claim 1, wherein the thin film transistor layer further comprises an organic insulating layer disposed on one side of the first metal layer away from the organic spacer layer, the thin film transistor layer is provided with a second groove in the thinning bending sub-area, the second groove passes through the organic spacer layer and a portion of the organic insulating layer, and the touch trace extends to the bonding area through the second groove.

6. The display panel according to claim 5, wherein the thin film transistor layer further comprises an opening provided in the bending area, the organic insulating layer is filled in the opening and protrudes from a top surface of the opening, a bottom surface of the second groove penetrates into the organic insulating layer and is flush with the top surface of the opening.

7. The display panel according to claim 1, wherein the touch trace is between the display area and the bending area, and is not electrically connected with the first metal trace through any connection hole in the organic spacer layer.

8. The display panel according to claim 7, wherein in the bending area, the first metal trace is disposed in the regular bending sub-area.

9. The display panel according to claim 7, wherein the display panel further comprises:
An encapsulation layer disposed on one side of the thin film transistor layer away from the substrate, wherein the encapsulation layer covers the display area and extends to a portion between the display area and the bending area;
wherein the encapsulation layer and the organic spacer layer are at least partially overlapped between the display area and the bending area, and the touch trace is arranged to cover the encapsulation layer and the organic spacer layer between the display area and the bending area.

10. A display device, comprising a display panel and a device body, wherein the display panel and the device body are integrated;
the display panel comprises a display area, a bending area on one side of the display area, and a bonding area on one side of the bending area away from the display area, wherein the bending area comprises a regular bending sub-area and a thinning bending sub-area;
the display panel further comprises:
a substrate;
a thin film transistor layer disposed on one side of the substrate, wherein the thin film transistor layer comprises a first metal layer and an organic spacer layer disposed on one side of the first metal layer away from the substrate, and the first metal layer comprises at least one first metal trace starting from the display area and extending to the bonding area through the bending area; and
a touch metal layer disposed on one side of the thin film transistor layer away from the substrate, wherein the touch metal layer comprises a touch electrode disposed in the display area and a touch trace electrically connected to the touch electrode, and the touch trace passes through the thinning bending sub-area and extends to the bonding area;
wherein a thickness of the thin film transistor layer in the thinning bending sub-area is less than a thickness of the thin film transistor layer in the regular bending sub-area.

11. The display device according to claim 10, wherein the organic spacer layer comprises a first organic portion disposed in the display area and a second organic portion disposed in the bending area;
in the bending area, the first metal trace is disposed between the second organic portion and the substrate, the second organic portion is provided with a first groove in the thinning bending sub-area, and the touch trace extends to the bonding area through the first groove.

12. The display device according to claim 11, wherein the organic spacer layer comprises a planarization layer, a pixel definition layer, and a spacer layer which are sequentially stacked on the first metal layer;
in the bending area, a bottom surface of the first groove of the second organic portion at least penetrates into the pixel definition layer.

13. The display device according to claim 12, wherein in the bending area, the bottom surface of the first groove of the second organic portion penetrates into the planarization layer.

14. The display device according to claim 10, wherein the thin film transistor layer further comprises an organic insulating layer disposed on one side of the first metal layer away from the organic spacer layer, the thin film transistor layer is provided with a second groove in the thinning bending sub-area, the second groove passes through the organic spacer layer and a portion of the organic insulating layer, and the touch trace extends to the bonding area through the second groove.

15. The display device according to claim 14, wherein the thin film transistor layer further comprises an opening provided in the bending area, and the organic insulating layer is filled in the opening and protrudes from a top surface of the opening, and a bottom surface of the second groove penetrates into the organic insulating layer and is flush with the top surface of the opening.

16. The display device according to claim 10, wherein the touch trace is between the display area and the bending area, and is not electrically connected with the first metal trace through any connection hole in the organic spacer layer.

17. The display device according to claim 16, wherein in the bending area, the first metal trace is disposed in the regular bending sub-area.

18. The display device according to claim 16, wherein the display panel further comprises:
an encapsulation layer disposed on one side of the thin film transistor layer away from the substrate, wherein the encapsulation layer covers the display area and extends to a portion between the display area and the bending area;
wherein the encapsulation layer and the organic spacer layer are at least partially overlapped between the display area and the bending area, and the touch trace is arranged to cover the encapsulation layer and the organic spacer layer between the display area and the bending area.
